(19) United States
(12) Patent Application Publication
(10) Pub. No.: US 2013/0240823 A1
(43) Pub. Date: Sep. 19, 2013

(54) NON-VOLATILE MEMORY INCLUDING MULTILAYER MEMORY CELLS AND METHOD OF FABRICATING THE SAME

(71) Applicant: Euipil KWON, San Jose, CA (US)

(72) Inventor: Euipil KWON, San Jose, CA (US)

(21) Appl. No.: 13/761,720

(22) Filed: Feb. 7, 2013

(30) Foreign Application Priority Data
Mar. 13, 2012 (KR) 10-2012-0025607

(51) Int. Cl. H01L 45/00

(52) U.S. Cl. CPC H01L 45/1253
USPC 257/4; 438/382

(57) ABSTRACT

A non-volatile memory and a method of fabricating the same, more particularly, a non-volatile memory in which memory cells each includes an anti-fuse and a diode or a variable resistor and a diode are stacked in a multilayer laminate structure without increasing a horizontal area, to effectively utilize a vertical space and thereby significantly increase a degree of integration so that the memory cells are able to be highly integrated and perform high-speed operation, and a method of fabricating the non-volatile memory.

### CROSS-REFERENCE TO RELATED APPLICATION

This application claims priority under 35 U.S.C. §119 to Korean Patent Application No. 10-2012-0025607 filed on Mar. 13, 2012, the disclosure of which is hereby incorporated by reference in its entirety.

### BACKGROUND

1. Field

Embodiments of the inventive concept relate to a non-volatile memory and a method of fabricating the same, and more particularly, to a non-volatile memory in which memory cells each including an anti-fuse and a diode or a variable resistor and a diode are stacked in a multilayer laminate structure without increasing a horizontal area, to effectively utilize a vertical space and thereby significantly increase a degree of integration so that the memory cells can be highly integrated and perform high-speed operation, and a method of fabricating the non-volatile memory.

2. Description of Related Art

Korean Patent Registration No. 10-0904771 relates to a three-dimensional integrated circuit structure and method making the same, and more particularly, to a three-dimensional IC structure including a monocrystalline semiconductor layer having a plurality of devices, one or more insulating layers applied on and beneath the monocrystalline semiconductor layer, and lines and connection lines arranged in the insulating layers, wherein the lines and the connection lines connect the plurality of devices directly or indirectly to each other.

Also, Korean Laid-open Patent Application No. 1997-0067848 relates to a semiconductor memory device including an access transistor T for accessing information of word lines, a storage node capacitor C for storing information stored through bit lines according to operation of the access transistor T, and a charge-up transistor P for supplying charges to the storage node capacitor C so that charges are continuously supplied to the storage node capacitor C to thereby improve the processing speed of the semiconductor memory device, and a method of fabricating the semiconductor memory device.

Generally, in a non-volatile semiconductor memory, information stored in memory cells is maintained even when no power is supplied.

A non-volatile memory according to the inventive concept includes memory cells configured to include a structure in which an intermediate layer between first and second electrodes is an insulating layer or a variable resistor.

If an intermediate layer configuring a memory cell is an insulating layer, by applying a high voltage for programming to both electrodes (that is, first and second electrodes) with the insulating layer therebetween to cause breakdown, a resistive path is made so that the insulating layer changes from a non-conductive state to a conductive state. The insulating layer becomes an anti-fuse device.

If the insulating layer is in the conductive state, the memory cell is in a programmed state in which data “0” is stored in the memory cell, whereas if the insulating layer is in the non-conductive state, the memory cell is in an unprogrammed state in which data “1” is stored in the memory cell. However, it is also possible that the conductive state is defined as a state in which data “1” is stored in the memory cell, and the non-conductive state is defined as a state in which data “0” is stored in the memory cell.

If the intermediate layer configuring the memory cell is a variable resistor, the variable resistor may be made of a variable-resistance material or a phase change material.

When the variable resistor configuring the memory cell is made of a variable-resistance material, if a voltage higher than a set voltage is applied to first and second electrodes with the variable resistor therebetween, the variable resistor goes into a low resistance state, and if a voltage higher than a reset voltage is applied to the first and second electrodes, the variable resistor goes into a high resistance state. Accordingly, it can be defined that if the variable resistor is in the low resistance state, data “1” is stored in the memory cell, whereas if the variable resistor is in the high resistance state, data “0” is stored in the memory cell. However, it is also possible that the low resistance state is defined as a state in which data “0” is stored, and the high resistance state is defined as a state in which data “1” is stored.

The variable-resistance material may be perovskite, a transition metal oxide, chalcogenide, etc.

Memories fabricated using variable-resistance materials can be classified into several types according to the kinds of the variable-resistance materials. First, there is the case where a material, such as a material exhibiting the property of colossal magnetoresistance (CMR), Pr1-xCaxMn03 (PCMO), etc., is inserted between electrodes to use a change in resistance due to an electric field. Second, there is the case where a bicomponent oxide, such as Nb₂O₅, TiO₂, NiO, Al₂O₃, etc., is manufactured to have a non-stoichiometrc compound to use it as a variable-resistance material. Third, there is the case of using a change in resistance due to a change in threshold voltage of an ovonic switch while maintaining an amorphous structure with a chalcogenide material, without making high current flow to change the phase, like a phase change RAM (PRAM). Fourth, there is a method of changing the state of resistance by doping a ferroelectric material, such as SrTiO₃, SrZrO₃, etc., with chrome (Cr), niobium (Nb), etc. Finally, there is a programmable metallization cell (PMC) in which two resistance states are made depending on if a conductive channel is formed in a medium due to an electrochemical reaction by doping a solid state electrolyte such as GeSe with silver (Ag) having high ion mobility. In addition, a material or a method capable of implementing two stable resistance states to obtain memory properties has been reported.

If the variable resistor configuring the memory cell is made of a phase transition material, it can be defined that if the phase transition material is in a low-resistance state, data “1” is stored, and if the phase transition material is in a high-resistance state, data “0” is stored. However, it is also possible that the low-resistance state is defined as a state in which data “0” is stored, and the high-resistance state is defined as a state in which data “1” is stored. The phase transition material is a material that phase-transitions to a crystalline state or an amorphous state in response to application of a specific current. When the phase transition material is in the crystalline state, this corresponds to a low-resistance state, and when the phase transition material is in the amorphous state, this corresponds to a high-resistance state.

Since memory cells are arranged in row and columns to configure a memory array, the memory cells should include transistors or diodes so that the memory cells can be selectively accessed.

In order to increase a degree of integration of a memory device, microfabrication technologies for integrating more memory cells than in a horizontal structure have been developed.

Conventional horizontal structures were dependent on microfabrication technologies having physical limitations in integration.

Accordingly, a new structure capable of increasing a degree of integration while deviating from conventional horizontal structures, and a fabrication method thereof, are needed.

### SUMMARY

An embodiment of the inventive concept provides a non-volatile memory in which memory cells each configured to include an anti-fuse and a diode or a variable resistor and a diode are stacked in a multilayer laminate structure in order to increase a degree of integration, and a method of fabricating the non-volatile memory.

Another embodiment of the inventive concept provides a structure for improving an interconnection method of memory cells without increasing an area, in order to reduce the resistance of connection lines connecting the memory cells to each other, and a method of fabricating the structure.

In accordance with an aspect of the inventive concept, there is provided a non-volatile memory, wherein a plurality of semiconductor layers are stacked on a semiconductor substrate to form a multilayered semiconductor layer, a plurality of interlayer insulating layers are respectively formed between the semiconductor substrate and the lowest one of the semiconductor layers and between the semiconductor layers, a plurality of first step height cells and a plurality of second step height cells having a different step height than the first step height cells are formed on the semiconductor substrate or on each semiconductor layer of the multilayered semiconductor layer, each of the first step height cells and the second step height cells is configured to have one of a multilayer laminate structure including a conductive layer (a first electrode)—a variable resistor (an intermediate layer)—a conductive layer (a second electrode)—a semiconductor layer, a multilayer laminate structure including a conductive layer (a first electrode)—a variable resistor (an intermediate layer)—a semiconductor layer (a second electrode), and a multilayer laminate structure including a conductive layer (a first electrode)—an insulating layer (an intermediate layer)—a conductive layer (a second electrode)—a semiconductor layer, and a multilayer laminate structure including a conductive layer (a first electrode)—an insulating layer (an intermediate layer)—a semiconductor layer (a second electrode), the first step height cells are formed with respect to a horizontal surface and have a greater step height than the second step height cells, and the second step height cells are formed with respect to a horizontal surface and have a lesser step height than the first step height cells, so that a plurality of memory cells are configured in a multilayer laminate structure.

The intermediate layer may be a data storage area, and configured with an insulating layer or a variable resistor. Hereinafter, for convenience of description, a structure in which the intermediate layer is an insulating layer is referred to as an A type, and a structure in which the intermediate layer is a variable resistor is referred to as a B type.

In some embodiments, each of the semiconductor layers configuring the first step height cells and the second step height cells may include a low-concentration diffusion area and a high-concentration diffusion area, and the low-concentration diffusion area and the high-concentration diffusion area may be configured in a double-layer laminate structure.

In another embodiment, the high-concentration diffusion area may be formed below the low-concentration diffusion area in a double-layer laminate structure, and a specific resistance of the high-concentration diffusion area may be lower than a specific resistance of the low-concentration diffusion area, so that the high-concentration diffusion area is used as a word line or a bit line, thereby increasing operating speed without increasing a horizontal area.

In still another embodiment, the first step height cells may be formed with respect to the surface of the semiconductor substrate or the surface of the semiconductor layer, and the second step height cells may be formed with respect to the bottom surfaces of trenches.

In yet another embodiment, the first electrode may be connected to the word line and the low-concentration diffusion area or the high-concentration diffusion area of each semiconductor layer may be connected to the bit line, or the first electrode may be connected to the bit line and the low-concentration diffusion area or the high-concentration diffusion area of the semiconductor layer may be connected to the word line, and the first step height cells or the second step height cells may be formed at intersections of word lines and bit lines as seen from the top.

In accordance with another aspect of the inventive concept, there is provided a method of fabricating a non-volatile memory, including: forming a plurality of first step height cells and a plurality of second step height cells on a semiconductor substrate by forming a plurality of trenches in the semiconductor substrate in a direction corresponding to areas in which the second step height cells are to be formed, forming a plurality of sidewall spacers on the sidewalls of the trenches, forming a plurality of diffusion areas in a self-alignment manner, forming the first step height cells on the surface of the semiconductor substrate, forming the second step height cells on bottom surfaces of the trenches, and forming a plurality of first electrodes of the first step height cells and the second step height cells; forming an interlayer insulating layer on the semiconductor substrate on which the first step height cells and the second step height cells are formed; applying a semiconductor layer on the interlayer insulating layer; and forming a plurality of first step height cells and a plurality of second step height cells on the semiconductor layer by forming a plurality of trenches in the semiconductor substrate in a direction corresponding to areas in which the second step height cells are to be formed, forming a plurality of sidewall spacers on the sidewalls of the trenches, forming a plurality of diffusion areas in a self-alignment manner, forming the first step height cells on the surface of the semiconductor substrate, forming the second step height cells on bottom surfaces of the trenches, and forming a plurality of first electrodes of the first step height cells and the second step height cells, wherein each of the first step height cells and the second step height cells has one of a multilayer laminate structure including a conductive layer (a first electrode)—a variable resistor (an intermediate layer)—a conductive layer (a second electrode)—a semiconductor layer, a multilayer laminate structure including a conductive layer (a first electrode)—a variable resistor (an intermediate layer)—a semiconductor layer (a second electrode), and a multilayer laminate structure including a conductive layer (a first electrode)—an insulating layer (an intermediate layer)—a conductive layer (a second electrode)—a semiconductor layer, and a multilayer laminate structure including a conductive layer (a first electrode)—an insulating layer (an intermediate layer)—a semiconductor layer (a second electrode).

In some embodiments, each of the semiconductor layers configuring the first step height cells and the second step height cells may include a low-concentration diffusion area and a high-concentration diffusion area, and the low-concentration diffusion area and the high-concentration diffusion area may be configured in a double-layer laminate structure.

In another embodiment, each high-concentration diffusion area may be formed by doping to a high concentration with a dopant that is complementary to the semiconductor substrate or the semiconductor layer, and each low-concentration diffusion area may be formed by doping to a low concentration with the dopant, so that the high-concentration diffusion area is formed below the low-concentration diffusion area in a double-layer laminate structure, thereby increasing operating speed without increasing a horizontal area.

In still another embodiment, in the case where the insulating layer (the intermediate layer) configuring the first step height cells and the second step height cells is thermally grown on the conductive layer (the second electrode), a polycrystalline silicon layer may be deposited on the conductive layer (the second electrode) and patterned before the insulating layer (the intermediate layer) is thermally grown, in order to prevent the thickness or properties of the insulating layer grown on the conductive layer (the second electrode) from changing from the thickness or properties of an insulating layer grown on a semiconductor surface.

Therefore, according to the embodiment as described above, the following effects can be obtained.

By additionally forming high concentration diffusion areas below low concentration diffusion areas when forming memory cells on each semiconductor layer, it is possible to increase operation speed by reducing resistance without having to increase horizontal area.

Since neighboring memory cells are vertically separated from each other, the interval between memory cells can be reduced, resulting in reduction in horizontal area and increase in degree of integration.

By stacking a plurality of semiconductor layers in a multilayer laminate structure and forming memory cells on each semiconductor layer, it is possible to significantly increase degree of integration in proportion to the number of semiconductor layers with memory cells, compared to a conventional horizontal structure.

### BRIEF DESCRIPTION OF THE DRAWINGS

The foregoing and other features and advantages of the inventive concepts will be made apparent by describing in detail preferred embodiments of the inventive concepts, as illustrated in the accompanying drawings, throughout which the same reference numerals are used to denote the same respective elements. The drawings are not necessarily to scale, emphasis instead being placed upon illustrating the principles of the inventive concepts. In the drawings:

FIG. 1 shows a cross-sectional view of a conventional anti-fuse device when the anti-fuse device has not been programmed and an equivalent circuit diagram of the unprogrammed state;

FIG. 2 shows a cross-sectional view of the conventional anti-fuse device when the anti-fuse device has been programmed and an equivalent circuit diagram of the programmed state;

FIG. 3 shows a cross-sectional view of another conventional anti-fuse device when the anti-fuse device has not been programmed and an equivalent circuit diagram of the unprogrammed state;

FIG. 4 shows a cross-sectional view of the other conventional anti-fuse device when the anti-fuse device has been programmed and an equivalent circuit diagram of the programmed state;

FIG. 5A is a 3-dimensional view of a multilayer memory array according to an embodiment of the inventive concept;

FIG. 5B is a 3-dimensional view of a multilayer memory array according to another embodiment of the inventive concept;

FIG. 5C is a schematic cross-sectional view of a multilayer memory array according to an embodiment of the inventive concept;

FIG. 5D is a schematic cross-sectional view of a multilayer memory array according to an embodiment of the inventive concept, in which the bottom layer is a logic circuit layer formed on a semiconductor substrate;

FIG. 5E shows a layout of a single-layer memory array according to an embodiment of the inventive concept;

FIG. 6 is a cross-sectional view of the single-layer memory array shown in FIG. 5E, cut along line A-A′;

FIG. 7 is a cross-sectional view of the single-layer memory array shown in FIG. 5E, cut along line B-B′;

FIG. 8 is a cross-sectional view of the single-layer memory array shown in FIG. 5E, cut along line C-C′;

FIG. 9 is a circuit diagram of the single-layer memory array shown in FIG. 5E;

FIG. 10 is a circuit diagram of the single-layer memory array shown in FIG. 5E, for explaining programming and read operations with respect to a memory array according to an embodiment of the inventive concept;

FIG. 11 shows a write circuit and a part of a column decoder for transferring data to a memory array according to an embodiment of the inventive concept;

FIG. 12 is a timing diagram for when data is programmed in a memory device according to an embodiment of the inventive concept;

FIG. 13 shows a read circuit and a column decoder for explaining a method in which data stored according to the inventive concept is read through a sense amplifier;

FIG. 14 is a timing diagram for when stored data is read from the memory device according to the embodiment of the inventive concept;

FIG. 15 is a block diagram showing the memory device according to the embodiment of the inventive concept;

FIG. 16 is a cross-sectional view of a semiconductor substrate prepared in order to fabricate the memory array according to the embodiment of the inventive concept;

FIG. 17 is a cross-sectional view of the semiconductor substrate after trenches are formed in the semiconductor substrate in order to fabricate the memory array according to the embodiment of the inventive concept;

FIG. 18 is a cross-sectional view of the semiconductor substrate after sidewall spacers are formed in order to fabricate the memory array according to the embodiment of the inventive concept;

FIG. 19A is a cross-sectional view of the semiconductor substrate after ions are implanted into high-concentration diffusion areas in order to fabricate the memory array according to the embodiment of the inventive concept;

FIG. 19B is a cross-sectional view of the semiconductor substrate after ions are implanted into low-concentration diffusion areas in order to fabricate the memory array according to the embodiment of the inventive concept;

FIG. 20 is a cross-sectional view of the semiconductor substrate after a silicide layer is formed in order to fabricate the memory array according to the embodiment of the inventive concept;

FIG. 21 is a cross-sectional view of the semiconductor substrate after an insulating layer is formed in order to fabricate the memory array according to the embodiment of the inventive concept;

FIG. 22A is a cross-sectional view of the semiconductor substrate after a metal layer is formed in order to fabricate the memory array according to the embodiment of the inventive concept;

FIG. 22B is a cross-sectional view of the semiconductor substrate after an interlayer insulating layer is deposited in order to fabricate the memory array according to the embodiment of the inventive concept;

FIG. 22C is a cross-sectional view of the semiconductor substrate after a semiconductor layer is grown and formed on the interlayer insulating layer in order to fabricate the memory array according to the embodiment of the inventive concept;

FIG. 23 is a cross-sectional view of the semiconductor substrate when no silicide layer is formed in order to fabricate the memory array according to the embodiment of the inventive concept;

FIG. 24 shows a cross-sectional view of a conventional memory cell, and an equivalent circuit; and

FIG. 25 shows a cross-sectional view of a memory cell according to an embodiment of the inventive concept, and an equivalent circuit.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described in detail with reference to the appended drawings.

The inventive concept may be applied to a semiconductor substrate configured with a bulk silicon wafer or a silicon-on-insulator (SOI) thin film.

A state in which no resistive path exists in an oxide layer used as an anti-fuse is defined as a state in which data “1” is stored, and a state in which a resistive path exists in the oxide layer is defined as a state in which data “0” is stored. However, it is also possible that a state in which no resistive path exists in an oxide layer used as an anti-fuse is defined as a state in which data “0” is stored, and a state in which a resistive path exists in the oxide layer is defined as a state in which data “1” is stored.

With regard to read and write circuits and read and write operations, for convenience of description, data buses are assumed to be 2-bit data buses. In the following description, bit lines are referred to as BL0 and BL1, global bit lines are referred to as GBL0 and GBL1, write data input signals are referred to as WD0 and WD1, and read data output signals are referred to as RD0 and RD1.

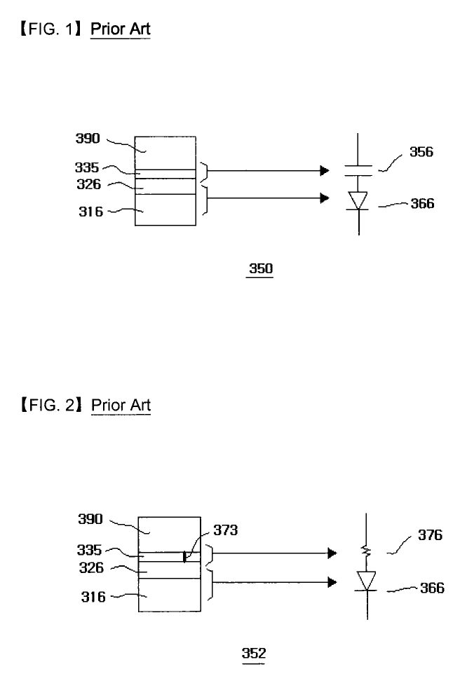

A conventional memory cell is shown in FIGS. 1 and 2. The memory cell has a multilayer laminate structure including conductive layer-insulating layer-conductive layer-semiconductor layer.

FIG. 1 shows a cross-sectional view of a memory cell when the memory cell has not been programmed and an equivalent circuit diagram of the unprogrammed state. As shown in FIG. 1, a thin insulating layer 335 is interposed between a first electrode 390 formed of a conductor and a second electrode 326 formed of a metal, thereby forming a capacitor 356.

Also, as shown in FIG. 1, due to the contact between the second electrode 326 formed of the metal and a diffusion area 316 doped with a low concentration of P-type or N-type dopant, a Schottky diode 366 is formed.

FIG. 2 shows a state in which the insulating layer 335 has been programmed in the memory cell shown in FIG. 1. As shown in FIG. 2, a resistive path 373 is made in the insulating layer 335 so that the insulating layer 335 changes from a non-conductive state to a conductive state.

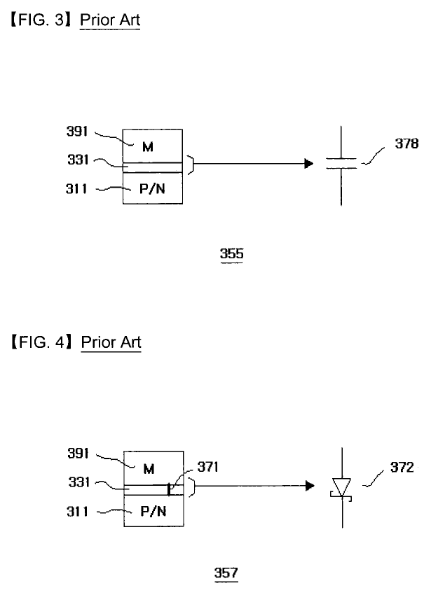

Another conventional memory cell is shown in FIGS. 3 and 4. The memory cell has a multilayer laminate structure including conductive layer (first electrode)-insulating layer (intermediate layer)-semiconductor layer (second electrode).

FIG. 3 shows a cross-sectional view of the memory cell when the memory cell has not been programmed and an equivalent circuit diagram of the unprogrammed state. As shown in FIG. 3, a thin insulating layer 331 is interposed between a first electrode formed of a metal and a second electrode 311 formed of a semiconductor doped with a low concentration of dopant, thereby electrically forming a capacitor 378.

FIG. 4 shows a cross-sectional view of the memory cell shown in FIG. 3 when the insulating layer 331 has been programmed and an equivalent circuit diagram of the programmed state.

As shown in FIG. 4, a resistive path 371 is made in the insulating layer 331 so that the insulating layer 331 changes from a non-conductive state to a conductive state. Accordingly, due to the structure in which the first electrode 391 formed of the metal contacts the second electrode 311 formed of the semiconductor, a Schottky diode 372 is formed.

When the memory cell is programmed, a sufficiently high voltage is applied across an anti-fuse which is the insulating layer 331 so that breakdown occurs in the anti-fuse to make a resistive path. The sufficiently high voltage is defined as a VAF voltage. Hereinafter, an embodiment in which the insulating layer is an oxide layer will be described.

Preferably, a VCC voltage is set to a level in which an electric field applied to a gate oxide layer is about 5 MV/cm, and an electric field required for causing gate breakdown in the gate oxide layer is about 20 MV/cm.

For example, if a gate length is 130 nm and the thickness of a gate oxide layer is 2.3 nm, a VCC voltage is preferably set to about 1.2 V, and a VAF voltage for causing gate breakdown is preferably set to about 5 V. Accordingly, in this case, a VPP voltage for programming is preferably set to about 5.3 V.

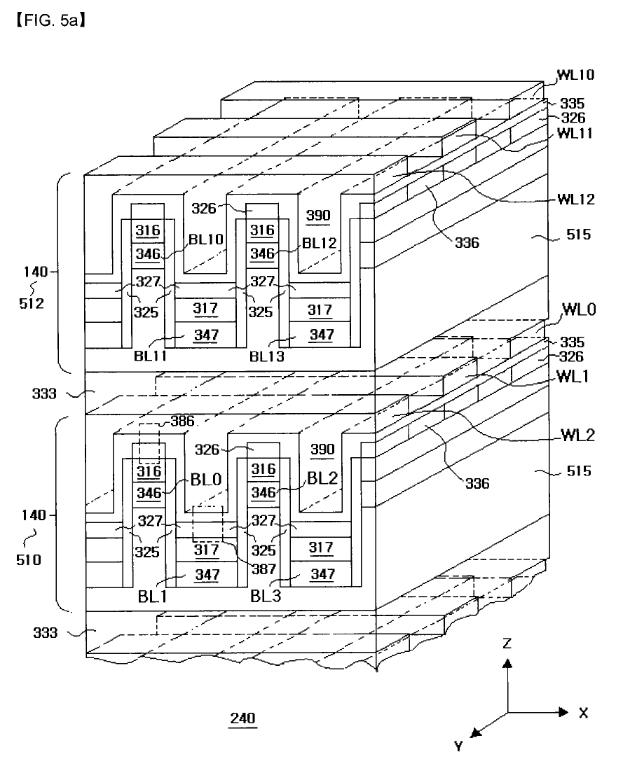

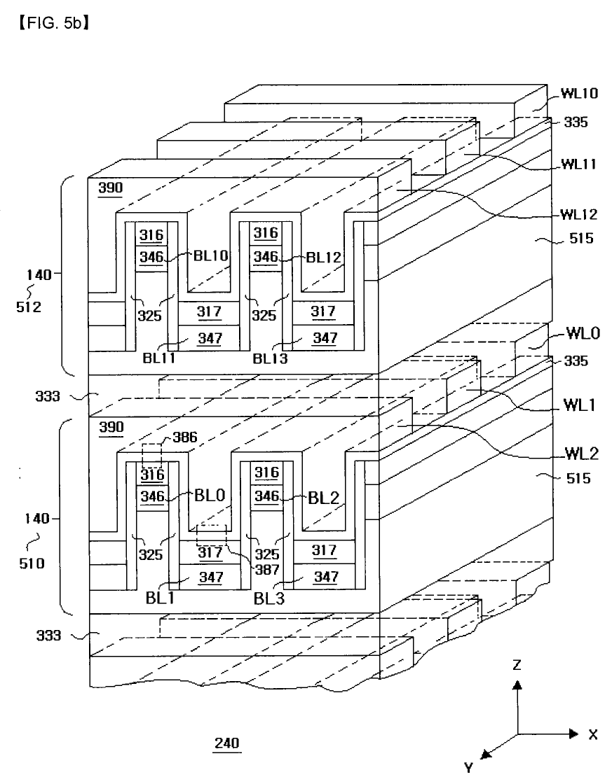

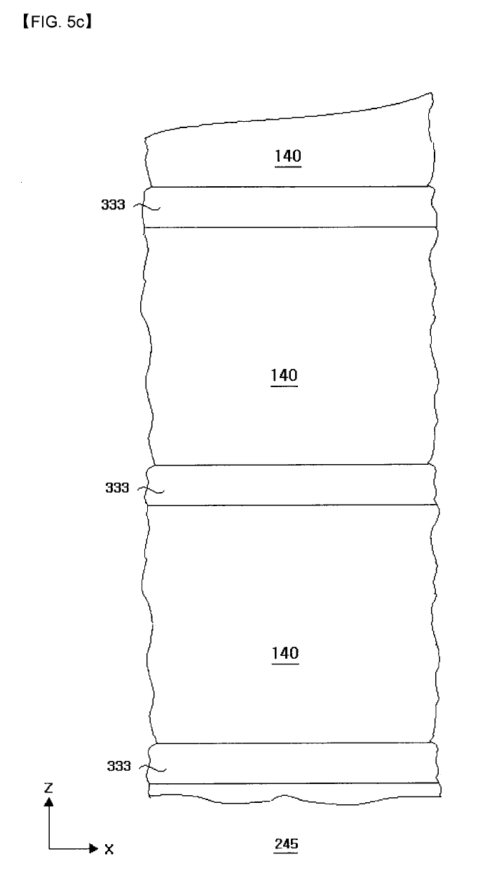

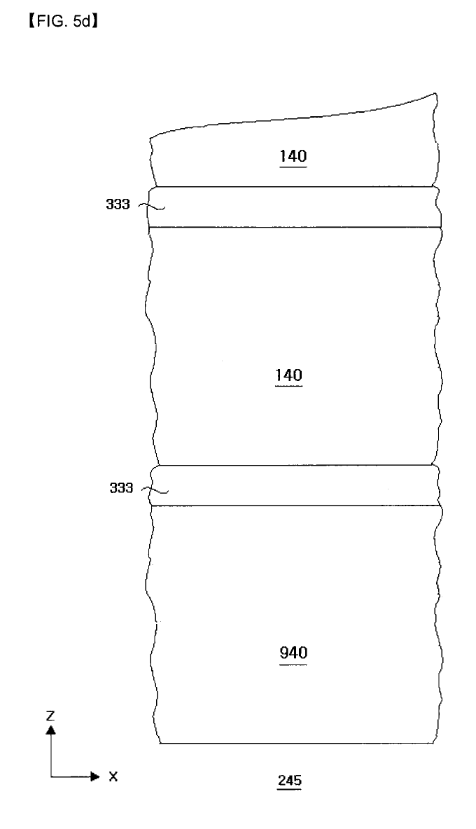

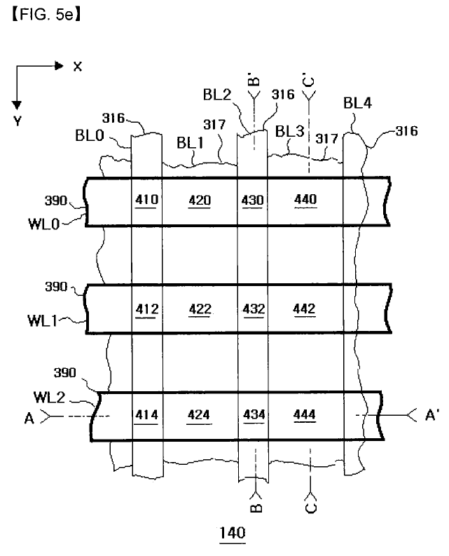

The 3-dimensional view of a multilayer memory array according to an embodiment of the inventive concept is shown in FIGS. 5A and 5B.

As shown in FIGS. 5A and 5B, memory arrays 140 are stacked vertically with an interlayer insulating layer 333 therebetween to thereby form a multilayer memory array.

The interlayer insulating layer 333 is applied on a single-layer memory array 510, and another single-layer memory array 510 is applied on the interlayer insulating layer 333.

As shown in FIG. 5A, each memory array 140 includes memory cells formed on a semiconductor layer 515.

In the memory array 510, word lines are arranged in an X-axis direction, and bit lines are arranged in a Y-axis direction. Memory cells 386 and 387 are formed at intersections of the word lines and the bit lines.

For easy understanding, areas in which the memory cells 386 and 386 are formed are denoted by dotted rectangles.

As shown in FIG. 5A, each of the memory cells 386 and 387 denoted by the dotted rectangles has a multilayer laminate structure including conductive layer (390, a first electrode)—insulating layer (335, an intermediate layer)—conductive layer (326, a second electrode)—semiconductor layer (316 or 317, a low-concentration diffusion area).

In the case where the intermediate layer 335 is a variable resistor, each memory cell 386 or 387 may have a multilayer laminate structure including conductive layer (390, the first electrode)—variable resistor (335, the intermediate layer)—conductive layer (326, the second electrode)—semiconductor layer (316 or 317, the low concentration diffusion area).

As shown in FIG. 5A, in the memory cells, low-concentration diffusion areas 316 and 317 and high-concentration diffusion areas 346 and 347 are formed in a double-layer laminate structure. Since the low-concentration diffusion areas 316 and 317 are formed through doping with a low concentration of dopant, the-low concentration diffusion areas 316 and 317 have high specific resistance. Accordingly, the low concentration diffusion areas 316 and 317 cannot be effectively used as bit lines for high-speed operation due to their high specific resistance. In order to overcome this problem, a method of forming additional contacts and connection lines to be used as bit lines has been developed. However, the method requires additional vertical and horizontal spaces due to the addition of the connection lines, which increases a horizontal area and lowers a degree of integration.

In order to overcome this problem, the present inventor has configured memory cells in a double-layer laminate structure by forming the high-concentration diffusion areas 346 and 347 at lower locations than the low-concentration diffusion areas 316 and 317 so as to be adjacent to the low-concentration diffusion areas 316 and 317, respectively, since the specific resistance of the high-concentration diffusion areas 346 and 347 is lower than the specific resistance of the low-concentration diffusion areas 316 and 317. In this way, by reducing the resistance of bit lines without increasing a horizontal area for addition of connection lines, memory cells that are advantageous for high-speed operation can be fabricated.

The memory cells are composed of two different kinds of memory cells. In the following description, the memory cells having the greater step height are referred to as first step height cells 386, and the memory cells having the lesser step height are referred to as second step height cells 387.

The 3-dimensional view of a multilayer memory array 240 according to another embodiment of the inventive concept is shown in FIG. 5B.

The multilayer memory array 240 shown in FIG. 5B is similar to the multilayer memory array 240 shown in FIG. 5A, except for the multilayer laminate structure including each memory cell.

In detail, each memory cell 386 or 387 of FIG. 5B has a multilayer laminate structure including conductive layer (390, a first electrode)—insulating layer (335, an intermediate layer)—semiconductor layer (316 or 317, a low-concentration diffusion area or a second electrode).

If the intermediate layer is a variable resistor, the memory cell 386 or 387 may have a multilayer laminate structure including conductive layer (390, the first electrode)—variable resistor (the intermediate layer)—semiconductor layer (316 or 317, the low-concentration diffusion area or the second electrode).

The multilayer memory arrays 240 shown in FIGS. 5A and 5B will be described in more detail with reference to FIGS. 5C and 5D.

FIGS. 5C and 5D are schematic cross-sectional views of multilayer memory arrays 245 according to embodiments of the inventive concept.

As shown in FIG. 5C, the multilayer memory array 245 has a structure in which single memory arrays 140 are stacked vertically.

In the multilayer memory array 245 shown in FIG. 5D, a bottom layer 940 is a circuit layer, instead of a memory array, formed on a semiconductor substrate. For example, by implementing the bottom layer 940 as a peripheral circuit for driving the multilayer memory array 245, instead of a memory array, it is possible to increase a degree of integration and achieve high-speed operation.

The layout of the lower single memory array 510 of the multilayer memory array 240 shown in FIG. 5A is shown in FIG. 5E. The layout is based on a plane defined by the x- and y-axis directions in FIG. 5A.

FIG. 5E shows a part of a single-layer memory array in which memory cells are arranged in a matrix form.

According to embodiments of the inventive concept, there are provided a multilayer memory array including a plurality of memory cells, a peripheral circuit for driving the multilayer memory array, and a method of operating the multilayer memory array.

As described above, according to an embodiment of the inventive concept, there is provided a method of connecting a word line to a bit line in a forward direction with respect to the diode of each memory cell.

There are two methods of connecting a word line to a bit line with respect to each memory cell. They are a method of connecting a word line to a bit line in a forward direction with respect to the diode (already formed or to be formed) of each memory cell, and a method of connecting the word line to the bit line in a backward direction with respect to the diode of the memory cell.

Since the memory cell has a structure in which both electrodes connect to word and bit lines, respectively, due to a diode connection when the intermediate layer changes from a non-conductive state to a conductive state, conversion is possible between the method of connecting the word line to the bit line in the forward direction and the method of connecting the word line to the bit line in the backward direction, since they have a complementary relationship.

As shown in FIG. 5E, word lines WL0, WL1, and WL2 are arranged in an x-axis direction, and bit lines BL0, BL1, BL2, and BL3 are arranged in a y-axis direction. Memory cells are formed at intersections of the word liens WL0, WL1, and WL2 and the bit lines BL0, BL1, BL2, and BL3.

Since neighboring bit lines are vertically separated from each other, the bit lines are adjacent to each other without any horizontal distance therebetween, as seen from the top. Accordingly, memory cells are also adjacent to each other without any horizontal distance therebetween, resulting in an increase in degree of integration.

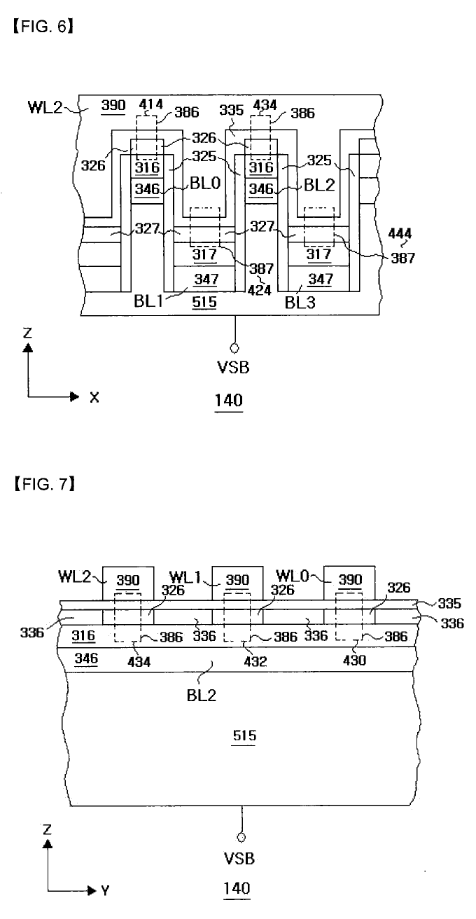

The cross-sectional view of the memory array 140 cut along line A-A′ is shown in FIG. 6.

FIG. 6 is a cross-sectional view of the memory array 140 of FIG. 5E, cut in a direction in which the word line WL2 extends.

The cross-sectional view shown in FIG. 6 is the same as the cross-sectional view of the single memory array 510 of FIG. 5A, cut in a direction in which the word line WL2 extends with respect to a plane defined by the X-axis and Y-axis directions.

In FIG. 6, the semiconductor layer 515 may be a P-type or an N-type, and in the current embodiment, the semiconductor layer 515 is assumed to be a P-type and connected to a body electrode VSB.

The memory cells 386 and 387 are two kinds of step height cells having different step heights.

As shown in FIG. 6, in areas in which cells 387 having the lesser step height are to be formed, trenches are formed in the semiconductor layer 515 at regular intervals, in order to provide memory cells including low-concentration diffusion areas 316 and 317 having different step heights.

The low-concentration diffusion areas 316 and 317 are doped with an N-type dopant which is complementary to the semiconductor layer 515, and become Schottky diodes by contacting the second electrodes 326 and 327 formed thereon, wherein the second electrodes 326 and 327 are formed of silicide or a metal.

As shown in FIG. 6, the low-concentration diffusion areas 316 and 317 and the high-concentration diffusion areas 346 and 347 are formed in a double-layer laminate structure. This has been described above.

As shown in FIG. 6, an oxide layer which is an insulating layer is formed on the second electrodes 326 and 327, and a first electrode 390 formed of polycrystalline silicon or a metal is formed on the oxide layer. The first electrode 390 is connected to the word line WL2.

In FIG. 6, the first and second step height cells 386 and 387 are denoted by dotted lines. The high-concentration diffusion areas 346 are connected to the bit lines BL0 and BL2, respectively. Also, the high-concentration diffusion areas 347 are connected to the bit lines BL1 and BL3, respectively.

The memory cells formed at the intersections of the word line WL2 and the bit lines BL0, BL1, BL2, and BL3, as shown in FIG. 5E, are shown in the cross-sectional view of FIG. 6. At the intersections 414 and 434 of the word line WL2 and the bit lines BL0 and BL2, as shown in FIG. 6, the first step height cells 386 including the diffusion areas 316 are formed with respect to the surface of the semiconductor layer 515.

Also, at the intersections 424 and 444 of the word line WL2 and the bit lines BL1 and BL3, as shown in FIG. 6, the second step height cells 387 including the diffusion areas 317 are formed with respect to the bottom surfaces of the trenches.

That is, the first step height cells 386 are formed with respect to the surface of the semiconductor layer 515, and the second step height cells 387 are formed with respect to the bottom surfaces of the trenches.

As shown in FIG. 6, each first step height cell 386 is a memory cell having a vertical multilayer laminate structure including conductive layer (390, the first electrode)-insulating layer (335, the intermediate layer)-conductive layer (326, the second electrode)-semiconductor layers (316 and 346).

Likewise, each second step height cell 387 is a memory cell having a vertical multilayer laminate structure including conductive layer (390)-insulating layer (335)-conductive layer (327)-semiconductor layers (317 and 347).

In the semiconductor layers 316, 317, 346, and 347 forming the first and second step height cells 386 and 387, the low-concentration diffusion areas 316 and 317 are doped to a low concentration with a dopant that is complementary to the semiconductor layer 515 configuring a body, and the high-concentration diffusion areas 346 and 347 are doped to a high concentration with a dopant similar to that of the low concentration diffusion areas 316 and 317. The high-concentration diffusion areas 346 and 347 are formed below the low-concentration diffusion areas 316 and 317 to form a double-layer laminate structure.

The low-concentration diffusion areas 316 and 317 are used to form Schottky diodes by contacting the conductive layers 326 and 327, and if the low-concentration diffusion areas 316 and 317 are used as word lines and bit lines, operating speed is reduced since the low-concentration diffusion areas 316 and 317 have high specific resistance. In order to overcome this problem, by forming the high-concentration diffusion areas 346 and 347 below the low-concentration diffusion areas 316 and 317, respectively, to form a double-layer laminate structure, it is possible to reduce the resistance of the low-concentration diffusion areas 316 and 317 without increasing a horizontal area since the high-density diffusion areas 346 and 347 have smaller specific resistance than the low-concentration diffusion areas 316 and 317.

In detail, as shown in FIG. 6, in order to prevent interference due to the insulating layer 335 interposed between the first electrode 390 and the semiconductor layer 515 and to suppress creation of parasitic transistors between the first and second step height cells 386 and 387, sidewall spacers 325 are formed on the sidewalls between the first and second step height cells 386 and 387. The reason is because leakage current may flow due to a resistive path made upon program operation when the insulating layer 335 is interposed between the first electrode 390 and the semiconductor layer 515. Even when the insulating layer 335 is a variable resistor, the variable resistor interposed between the first electrode 390 and the semiconductor layer 515 may cause leakage current.

Also, the reason is because the first electrode 390 functions as a gate, the insulating layer 335 functions as a gate oxide layer, and the diffusion areas 316 and 317 function as source and drain areas so that they together function as a MOS transistor.

In the above example, a case where the first step and second step height cells have a stack structure including the conductive layer (first electrode), the insulating layer, the conductive layer (second electrode) and the semiconductor layer has been described. However, the first and second step height cells may have a stack structure including the conductive layer (first electrode), the insulating layer, and the semiconductor layer (second electrode). Further, the semiconductor layer may include a P-N junction diode structure. When described with reference to FIG. 6, it may have a stack structure including the conductive layer 390, the insulating layer 335, the conductive layer 326 and the semiconductor layer 316 and 346. The semiconductor layer may be configured to include a P-N diode formed by joining a P-t e/N-type diffusion region 316 and a N-type/P-type diffusion region 346.

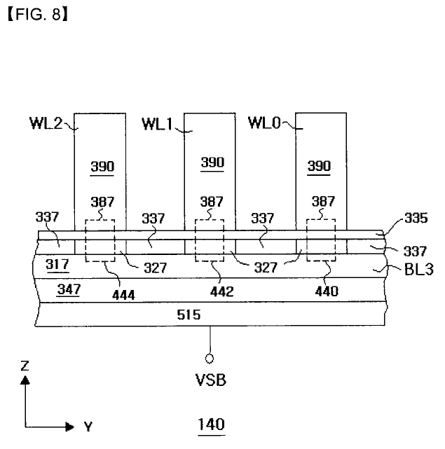

The cross-sectional view of the memory array 140, cut along line B-B′ of FIG. 5E is shown in FIG. 7.

FIG. 7 is a cross-sectional view of the memory array 140 cut in a direction in which the bit line BL2 of FIG. 5E extends.

The cross-sectional view shown in FIG. 7 is the same as the cross-sectional view of the single memory array 510 of FIG. 5A, cut in a direction in which the bit line BL2 extends with respect to a plane defined by the X-axis and Y-axis directions.

As shown in FIG. 7, in areas in which no trench is formed, the first step height cells 386 are formed with respect to the surface of the semiconductor layer 515. Areas of the first step height cells 386 are denoted by dotted lines in FIG. 7.

The memory cells shown in the cross-sectional view of FIG. 7 are formed at the intersections of the bit line BL2 and the word lines WL0, WL1, and WL2.

At the intersections, as shown in FIG. 7, the first step height cells 386 including the low-concentration diffusion areas 316 and the high-concentration diffusion areas 346 are formed with a greater step height than the second step height cells 387 (see FIG. 6) with respect to the surface of the semiconductor layer 515.

The second electrodes 326 are formed on the first step height cells 386, and the horizontal spaces between the second electrodes 326 are filled with an insulating layer 336.

The cross-sectional view of the memory array 140 cut along line C-C′ of FIG. 5E is shown in FIG. 8.

FIG. 8 is a cross-sectional view of the memory array 140 cut in a direction in which the bit line BL3 of FIG. 5E extends. The cross-sectional view shown in FIG. 8 is the same as the cross-sectional view of the single memory array 510 of FIG. 5A, cut in a direction in which the bit line BL3 extends with respect to a plane defined by the X-axis and Y-axis directions.

FIG. 8 shows memory cells formed at the intersections 440, 442, and 444 of the bit line BL3 and the word lines WL0, WL1, and WL2. At the intersections 440, 442, and 444, as shown in FIG. 8, the second step height cells 387 including the low-concentration diffusion areas 317 and the high-concentration diffusion areas 347 are formed with a lesser step height than the first step height cells 386 (see FIG. 7), that is, with a lesser step height than the surface of the semiconductor layer 515, with respect to the bottom surfaces of the trenches.

The second electrodes 327 are formed on the second step height cells 387, and the horizontal spaces between the second electrodes 327 are filled with an insulating layer 337.

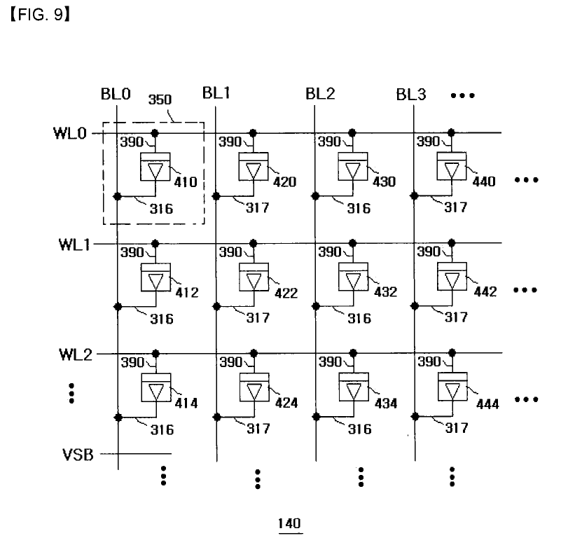

A circuit corresponding to the memory array 140 is shown in FIG. 9. In FIG. 9, for easy understanding, each memory cell is denoted by a symbol to indicate that it includes an anti-fuse and a diode.

As described above, a plurality of memory cells 350 are formed at intersections of word lines and bit lines.

As shown in FIG. 9, the memory array 140 has a structure in which the plurality of memory cells 350 are arranged in a matrix form and integrated.

As shown in FIG. 9, the bit line of each memory cell 350 is connected to the bit lines of the other memory cells so that the bit lines are arranged on columns to form bit line buses BL0, BL2, BL2, . . .

The bit line buses BL0, BL1, BL2, . . . are selected by a column decoder to be connected to global bit line buses GBL0, GBL1, GBL2, . . . so as to exchange data with the global bit line buses GBL0, GBL1, GBL2, . . . in association with a read circuit and a write circuit.

As shown in FIG. 9, the word line of each memory cell 350 is connected to the word lines of the other memory cells so that the word lines are arranged in rows to form word line buses WL0, WL1, WL3, WL3, WL4, . . . . The word lines are connected to the output terminals of a row decoder and selected by the row decoder.

The body of the memory cell 350 is a P-type or N-type semiconductor layer. The body of the memory cell 350 is shared by the other memory cells and connected in common to a body electrode VSB.

In the memory array 140, by programming the anti-fuses of memory cells selected by the word lines and bit lines, data is stored in the memory cells. The programming is performed according to the electrical states of bit lines selected by the column decoder and intersecting word lines selected by the row decoder.

According to an embodiment, in the memory array 140, a state in which no resistive path is made in the anti-fuse which is the oxide layer of the memory cell 350 is defined as a state in which data “1” is stored, and a state in which a resistive path is made in the anti-fuse is defined as a state in which data “0” is stored.

Accordingly, in the initial state, all the memory cells of the memory 140 are in the state in which data “1” is stored. In order to store data “0” in a selected memory cell 350, a resistive path should be made in an anti-fuse, which is the oxide layer of the memory cell 350. On the contrary, in order to store data “1” in a memory cell 350, no resistive path should be made in an anti-fuse, which is the oxide layer of the corresponding memory cell 350, even though the memory cell 350 is selected by a word line and a bit line. For this, a VPP voltage is applied to the selected bit line or the selected bit line goes to a floating state.

If a word line is selected during program operation, preferably, the VPP voltage is applied to the selected word line, and a voltage of 0V is pre-charged to the other non-selected word lines so that the non-selected word lines go to a floating state.

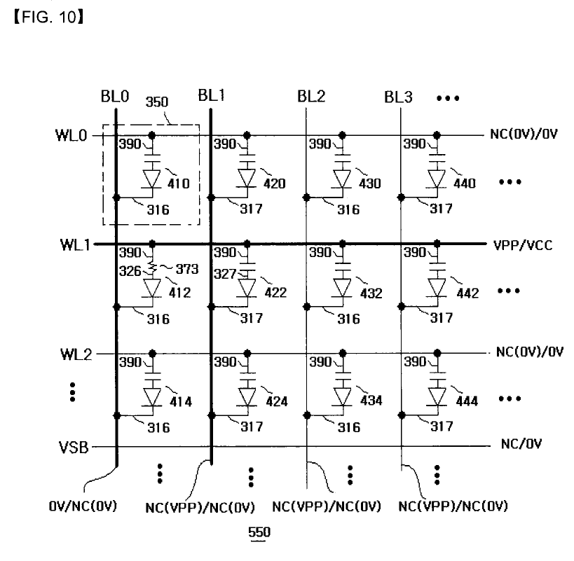

Hereinafter, an embodiment in which program operation is performed in a memory array 550 will be described with reference to FIG. 10.

FIG. 10 shows an equivalent circuit corresponding to the memory array 140 shown in FIG. 9 after the memory array 140 is programmed. In FIG. 9, each memory cell is assumed to have a structure in which an anti-fuse is connected in series to a diode. Accordingly, if the anti-fuse is in a non-conductive state, the anti-fuse functions as a capacitor, whereas if the anti-fuse is in a conductive state, the anti-fuse functions as a resistor.

FIG. 10 shows an embodiment in which a word line WL1 and bit lines BL0 and BL1 are selected. The selected word line WL1 and the selected bit lines BL0 and BL1 are denoted by bold lines for easy understanding. In the current embodiment, data “0” is stored in a memory cell 412 selected by the word line WL1 and the bit line BL0, and data “1” is stored in a memory cell 422 selected by the word line WL1 and the bit line BL1.

Word lines not selected during program operation go to a floating state pre-charged to a 0V voltage in advance, and the voltage of the selected word line WL1 rises to the VPP voltage from the 0V voltage. Also, the body electrode VSB goes to the 0V voltage or the floating state.

The non-selected bit lines BL2, BL3, . . . go to the VPP voltage or the floating state so that no forward voltage is applied to the diodes of the corresponding memory cells.

Since data “0” has to be stored through the bit line BL0 and data “1” has to be stored through the bit line BL1, a 0V voltage is applied to the bit line BL0 in order to store the data “0”, and the VPP voltage is applied to the bit line BL1 or the bit line BL1 goes to a floating state in order to store the data “1”.

The VPP voltage is applied to the selected word line WL1 and a voltage of 0 V is applied to the bit line BL0. As shown in FIG. 10, the VPP voltage is applied between both terminals of the memory cell 412 selected by the word line WL1 and the bit line BL0 so that the diode of the memory cell 412 is turned on.

Accordingly, the voltage of the second electrode 326 of the memory cell 412 rises to a diode threshold voltage, for example, a voltage of 0.2V to 0.3V.

As a result, a high voltage resulting from subtracting the diode threshold voltage from the VPP voltage is applied between the first electrode 390 and the second electrode 326 of the memory cell 412, and according to the embodiment described above with regard to the VPP voltage, since the VPP voltage is about 5.3V, a voltage of about 5V corresponding to the VAF voltage is applied between the first electrode 390 and the second electrode 326.

Accordingly, breakdown occurs in an anti-fuse which is an oxide layer between the first electrode 390 and the second electrode 326 so that a resistive path is made. That is, the memory cell 412 is programmed with data “0”.

Meanwhile, in the memory cell 422 selected by the word line WL1 and the bit line BL1, the second electrode 327 goes to a floating state although the diode of the memory cell 422 is turned on, since the bit line BL1 is in a floating state regardless of the word line WL1.

Accordingly, in the memory cell 422, no high voltage is applied between the first electrode 390 and the second electrode 327 although the VPP voltage is applied to the word line WL1 connected to the first electrode 390, and no resistive path is made since no breakdown occurs in an anti-fuse which is an oxide layer between the first electrode 390 and the second electrode 327. That is, the memory cell 422 is not programmed. In other words, since the memory cell 422 is maintained in an initial state, data stored in the memory cell 422 is “1”.

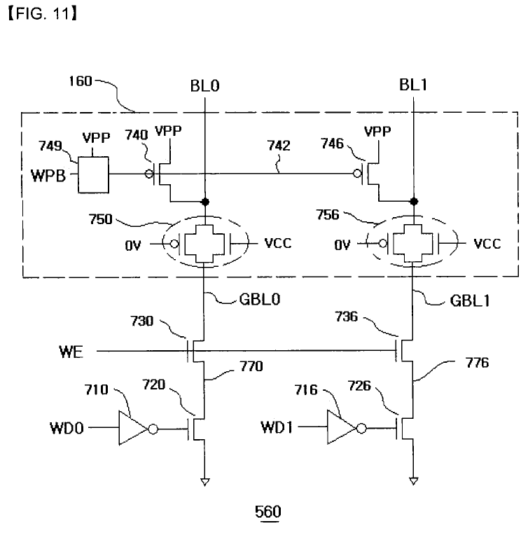

The selected bit lines BL0 and BL1 include a column decoder and a write circuit, and are paths through which data needed for program operation is input. FIG. 11 shows a part of the column decoder and the write circuit.

Referring to FIG. 11, an embodiment in which in the column decoder 160, bit lines BL0 and BL1 and global bit lines GBL0 and GBL1 are selected through transmission gates 750 and 756 selected and controlled by column decoding will be described below.

As shown in FIG. 11, in order to cause the channels of the transmission gates 750 and 756 selected by the column decoder 160 to become a conductive state, a VCC voltage and a 0V voltage are applied to the gates of each of the transmission gates 750 and 756. The column decoder 160 includes transistors 740 and 746 for pre-charging the bit lines BL0 and BL1 to the VPP voltage, and the transistors 740 and 746 are controlled by receiving a WPB signal.

The global bit lines GBL0 and GBL1 have the 0V voltage or the floating state according to a control or data of the write circuit.

As shown in FIG. 11, write data input signals WD0 and WD0 may apply the 0V voltage to the global bit lines GBL0 and GBL1 through inverters 710, 716, pull-down transistors 720 and 726, and pass transistors 730 and 736, in order to program the global bit lines GBL0 and GBL1, or the write data input signals WD0 and WD1 may cause the global bit lines GBL0 and GBL1 to go to the floating state in order to prevent the global bit lines GBL0 and GBL1 from being programmed.

According to an embodiment in which the memory array 560 is programmed, data “0” is stored through the bit line BL0, and data “1” is stored through the bit line BL1. Accordingly, the data input signal WD0 has a logic level “0”, and the data input signal WD1 has a logic level “1”.

Since it is necessary to be able to prevent the bit line BL0 or BL1 from being programmed, conversion from the VPP voltage to the floating state is preferable.

Accordingly, since the global bit lines GBL0 and GBL1 have to be pre-charged to the VPP voltage, the WPB signal goes to a logic level “0” before the word line WL1 is selected during a write cycle in a program mode.

With regard to this operation, FIG. 12 shows a write cycle timing 570. Since the data input signal WD0 has a logic level “0”, the voltage at the drain 770 of the pull-down transistor 720 goes to 0V via the inverter 710, and since the data input signal WD1 has a logic level “1”, the drain 776 of the pull-down transistor 726 goes to a floating state via the inverter 716.

Next, as shown in FIG. 12, since the WPB signal goes to a logic level “1”, the voltage at the gate 742 of bit line pre-charge transistors 740 and 746 reaches the VPP voltage via a level shifter 749 so that pre-charging of the bit lines BL0 and BL1 is terminated.

Then, as shown in FIG. 12, a WE signal goes to a logic level “1”. Thereby, the channels of the pass transistors 730 and 736 go to a conductive state so that the voltages on the global bit line GBL0 and the bit line BL0 go to 0V and the global bit line GBL1 and the bit line BL1 go to a floating state.

If the VPP voltage is applied to the word line WL1 to select the word line WL1, and the 0V voltage is applied to the bit line BL0, as shown in FIG. 12, the diode of the memory cell 412 (see FIG. 10) is turned on.

Accordingly, the voltage at the second electrode 326 of the memory cell 412 reaches the diode threshold voltage of 0.2 V to 0.3V, so that a high voltage is applied to the anti-fuse which is the oxide layer between the first electrode 390 and the second electrode 326 (see FIG. 6). Accordingly, breakdown occurs, and a resistive path is made. That is, the memory cell 412 is programmed and data “0” is stored in the memory cell 412. Meanwhile, since the diode of the memory cell 422 (see FIG. 10) is connected to the bit line BL1 so that a floating state is maintained even though charges are transferred between the memory cell 422 and the bit line BL1, no breakdown occurs in the anti-fuse which is the oxide layer between the first electrode 390 and the second electrode 327 so that the memory cell 422 is prevented from being programmed and data “1” is stored in the memory cell 422.

Next, as shown in FIG. 12, the voltage of the word line WL1 rises to the VCC voltage, and then the WE signal goes to a logic level “0”, so that the bit line pre-charge transistors 740 and 746 are turned on to thus again pre-charge the bit lines BL0 and BL1 to the VPP voltage. Thereby, write cycle operation is terminated.

Whether the programming has been correctly performed may be verified by performing a read cycle following the write cycle operation. By repeating write and read cycles, programming can be correctly performed, and defect processing can be performed by limiting the number of repetitions.

Data stored in a memory cell is read by determining whether or not a resistive path exists. That is, data stored in a memory cell selected by a word line is transferred to a selected bit line, and the data is converted into digital data by a sense amplifier that can sense and amplify the electrical states of bit lines.

An embodiment in which a read operation is performed in the memory array 550 as shown in FIG. 10 will be described below.

For example, it is assumed that a resistive path is made in the anti-fuse, which is the oxide layer between the first electrode 390 and the second electrode 326 of the memory cell 412, so that data “0” is stored, and no resistive path is made in the anti-fuse, which is the oxide layer between the first electrode 390 and the second electrode 327 of the memory cell 422, so that data “1” is stored.

For easy understanding, an equivalent circuit showing the resistive path 373, corresponding to the case where data “0” is stored, is shown in FIG. 10.

Referring to FIG. 10, the resistive path 373 between the first electrode 390 and the second electrode 326 of the memory cell 412 in which data “0” is stored is shown as a resistor. This is criteria for determining the stored data to be “0” in a read operation which will be described later.

In the embodiment of FIG. 10, the word line WL1 and the bit lines BL0 and BL1 are selected.

The VCC voltage is applied to the non-selected bit lines BL2, BL3, . . . , or the non-selected bit lines BL2, BL3, . . . go to the floating state pre-changed in advance to the 0V voltage.

Also, according to an embodiment, the 0V voltage is applied to the body electrode VSB and the non-selected word lines WL0, WL3, WL3, . . . .

The bit lines BL0 and BL1 have to be pre-charged to the 0V voltage before the word line WL1 is selected and the VCC voltage is applied to the word line WL1. If the word line WL1 is selected and the VCC voltage is applied to the word line WL1, the word line WL1 goes to a conductive state through a diode and a resistive path 373 connected to the bit line BL0. Therefore, the voltage at the bit line BL0 reaches a voltage lower by the diode threshold voltage than the VCC voltage applied to the word line WL1.

Also, if the VCC voltage is applied to the word line WL1, a diode connected to the bit line BL1 may be turned on since the diode is connected in series to the second electrode 327 of the memory cell 422.

However, the bit line BL1 is maintained at a voltage close to the 0V voltage pre-charged in advance to the floating state. The reason is because there is little change in voltage of the bit line BL1 since the parasitic capacitance of the bit line BL1 is relatively much greater than the second electrode 327, even though charges are transferred between the bit line BL1 and the second electrode 327 of the memory cell 422.

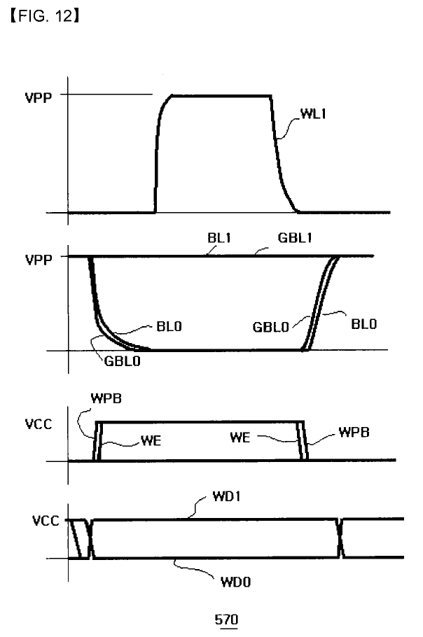

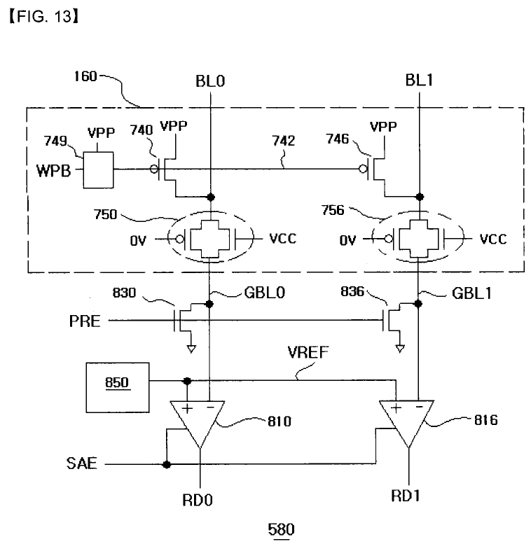

FIG. 13 shows a circuit for reading data stored in a memory cell, according to an embodiment of the inventive concept.

As shown in FIG. 13, bit lines BL0 and BL1 are connected to global bit lines GBL0 and GBL1, respectively, through a column decoder 160, and selected by column decoding.

The column decoder 160 is not an additional device but a write circuit. In FIG. 13, the column decoder 160 is shown as a separate device for easy understanding in association with a read circuit.

There are provided transistors 830 and 836, as global bit line pre-charge circuits, for pre-charging the global bit lines GBL0 and GBL1 to the 0V voltage, and sense amplifiers 810 and 816 for reading data regarding the electrical states of the bit lines BL0 and BL1 transferred to the global bit lines GBL0 and GBL1 and stored.

As shown in FIG. 13, the sense amplifiers 810 and 816 operate when SAE goes to a logic level “1”, amplify differences between a reference voltage VREF and input signals GBL0 and GBL1, respectively, latch the amplified voltage differences, and output the latched voltage differences as output signals RD0 and RD1, respectively,

The sense amplifiers 810 and 816 may be latch-type sense amplifiers. Since the latch-type sense amplifier is well-known in the art, a detailed description therefor will be omitted.

If the stored data is “0”, the input signals GBL0 and GBL1 of the sense amplifiers 810 and 816 change to a “VCC-Vd (diode threshold voltage)” voltage from the 0V voltage, and if the stored data is “1”, the input signals GBL0 and GBL1 are maintained at a voltage close to the 0V voltage.

Accordingly, the reference voltage VREF may be set to half the “VCC-Vd” voltage, however, the reference voltage VREF may be set to a smaller value for high-speed operation.

The reference voltage VREF is assumed to be a voltage of 0.2V. The reference voltage VREF is provided from a VREF generator 850.

If SAE goes to a logic level “1”, the sense amplifiers 810 and 816 operate. If GBL0>0.2V, GBL>VREF so that RDO has a logic level “0”, and if GBL0<0.2V, RDO has a logic level “1”.

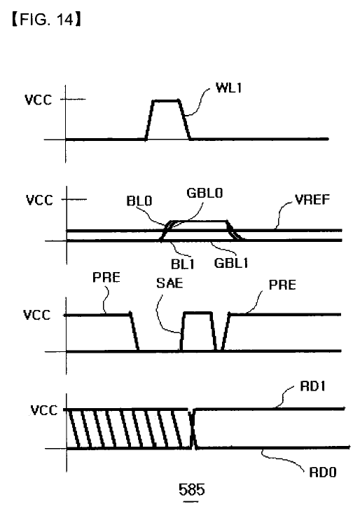

A read cycle timing regarding read operation is shown in FIG. 14. Referring to FIGS. 13 and 14, before the word line WL1 is selected to have a logic level “1”, PRE goes to a logic level “1” so that the global bit lines GBL0 and GBL1 are pre-charged to a 0V voltage by the pre-charge transistors 830 and 836.

Then, the word line WL1 is selected so that a VCC voltage is applied to the word line WL1, and the bit line BL0 is in a floating state pre-charged to the 0V voltage.

Referring again to FIG. 10, in the memory cell 412 in which the word line WL1 is connected to the bit line BL0, the resistive path 373 made in the anti-fuse is connected in series to the diode, and a forward voltage is applied to the diode to cause current to flow through the diode, so that the voltage of the bit line BL0 rises.

As a result, when the word line WL1 is selected, the voltages of the bit line BL0 and the global bit line GBL0 rise to the “VCC-Vd” voltage. In the current embodiment, it is assumed that the voltage of the global bit line GBL0 rises to a voltage of 0.5V.

If the word line WL1 is selected and the VCC voltage is applied to the word line WL1, in the memory cell 422 in which the word line WL1 is connected to the bit line BL1, no current flows through the diode after the anti-fuse is charged since there is no resistive path. Although charges may be transferred between the second electrode 327 of the memory cell 422 and the bit line BL1 through the diode, the bit lines BL1 and GBL1 are maintained at a voltage close to a 0V voltage since the parasitic capacitance of the bit line BL1 is relatively much greater than the second electrode 327.

As shown in FIGS. 13 and 14, if SAE goes to a logic level “1”, the voltage of the global bit line GBL0 is amplified to 0.5V higher than the reference voltage VREF of 0.2V by the sense amplifier 810, so that RDO is latched as a logic level “0” and output, and the voltage of the global bit line GBL1 is adjusted to 0V lower than the reference voltage VREF of 0.2V by the sense amplifier 816, so that RD1 is latched as a logic level “1” and output.

Next, the voltage of the word line WL1 becomes a 0V voltage and the SAE goes to a logic level “0”, so that the operations of the sense amplifiers 810 and 816 are stopped. As shown in FIG. 14, if the PRE goes to a logic level “1”, the global bit lines GBL0 and GBL1 are again pre-charged to the 0V voltage, so that the read cycle operation is terminated.

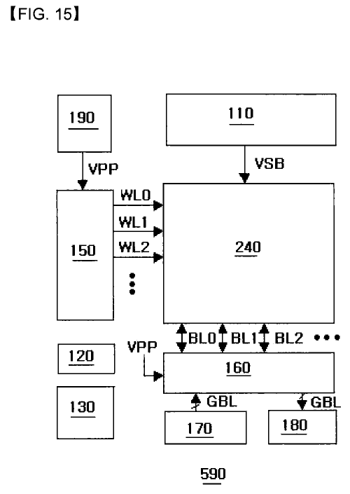

A memory device according to an embodiment of the inventive concept is shown in FIG. 15. The configuration of the memory device will be briefly described with reference to FIG. 15, below.

The memory device includes a multilayer memory array 240 and a VSB supplying unit 110 for generating VSB for the memory array 240.

Also, a VPP generator 190 generates a VPP voltage and supplies the VPP voltage to a row decoder 150 and a column decoder 160.

The row decoder 150 selects word lines in the multilayer memory array 240, and the column decoder 160 selects bit lines.

As shown in FIG. 15, the row decoder 150 and the column decoder 160 receive addresses from an input and output unit 130, and decode addresses under the control of a controller 120.

Since the row decoder 150 requires the VPP voltage for program operation, the row decoder 150 receives the VPP voltage from the VPP generator 190. The column decoder 160 includes a pre-charge circuit for pre-charging the voltage of bit lines to the VPP voltage and causing the bit lines to be in a floating state so that the bit lines are not programmed.

Also, there is a write circuit 170 for data write operation. The write circuit 170 receives data from the input and output unit 130, and transfers them to GBL that are global bit line buses GBL0, GBL1, GBL2, . . . under the control of the controller 120.

As shown in FIG. 15, there is a read circuit 180 for data read operation. Stored data is transferred to the GBL that are the global bit lines buses GBL0, GBL1, GBL2, . . . . Sense amplifiers sense and amply the electrical states of the GBL, convert the electrical states to digital signals, and transfer the digital signals to the input and output unit 130.

The input and output unit 130 performs interfacing between external and internal devices. The controller 120 receives instructions for write and read operation through the input and output unit 130, and interprets the instructions to control the related circuits.

The configuration of the memory device as described above may be modified. The memory device may be applied to various memory devices, such as DRAM or SRAM, as well as a one-time programmable (OTP) memory device, by including a fuse in a redundancy repair.

A method of fabricating a non-volatile memory, according to an embodiment of the inventive concept, includes: forming a plurality of first step height cells and a plurality of second step height cells on a semiconductor substrate by forming a plurality of trenches in the semiconductor substrate in a direction corresponding to areas in which the second step height cells are to be formed, forming sidewall spacers on the sidewalls of the trenches, forming a plurality of diffusion areas in a self-alignment manner, forming the first step height cells on the surface of the semiconductor substrate, forming the second step height cells on bottom surfaces of the trenches, and forming a plurality of first electrodes of the first step height cells and the second step height cells; forming an interlayer insulating layer on the semiconductor substrate on which the first step height cells and the second step height cells are formed; applying a semiconductor layer on the interlayer insulating layer; and forming a plurality of first step height cells and a plurality of second step height cells on the semiconductor layer by forming a plurality of trenches in the semiconductor substrate in a direction corresponding to areas in which the second step height cells are to be formed, forming sidewall spacers on the sidewalls of the trenches, forming a plurality of diffusion areas in a self-alignment manner, forming the first step height cells on the surface of the semiconductor substrate, forming the second step height cells on bottom surfaces of the trenches, and forming a plurality of first electrodes of the first step height cells and the second step height cells.

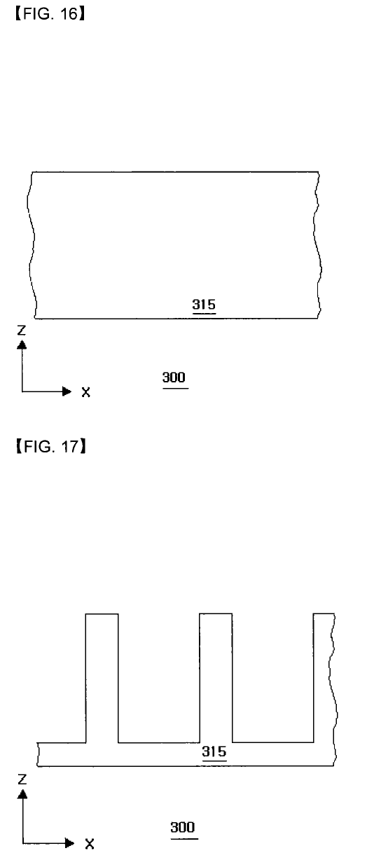

As shown in detail in FIG. 16, a semiconductor substrate 315 is thus prepared.

An embodiment of the inventive concept relates to the structure illustrated in FIG. 1. The embodiment related to the structure illustrated in FIG. 1 is aimed at describing a method of fabricating a semiconductor device including the structure illustrated in FIG. 3. Further, although the diode structure illustrated as an example in this case is a Schottky diode, since it can be easily modified into a P-N diode, the description using the P-N diode as an example will not be given.

The semiconductor substrate 315 is doped generally with a P-type dopant or an N-type dopant. In the present embodiment, it is assumed that the semiconductor substrate 315 is doped with a P-type dopant.

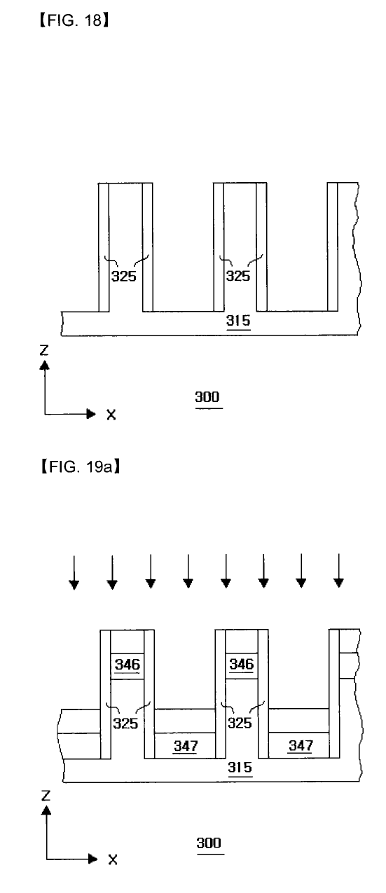

After the semiconductor substrate 315 is prepared, as shown in FIG. 17, trenches for forming second step height cells 387 (see FIG. 5A) are formed. The trenches are arranged on columns at regular intervals each corresponding to the width of each first step height cell 386 in order to form first step height cells 386 (see FIG. 5A) between neighboring trenches. The bottom areas of the trenches are areas in which the second step height cells 387 are formed. The depths of the trenches are preferably two or more times the total depth of diffusion areas since the diffusion areas 316 and 346 (see FIG. 19B) of the first step height cells 386 have to be sufficiently separated from the diffusion areas 317 and 347 (see FIG. 19B) of the neighboring second step height cells 387.

Next, as shown in FIG. 18, sidewall spacers 325 are formed on the sidewalls of the trenches.

Then, as shown in FIG. 19A, after forming single crystalline silicon for the diffusion regions of the second stepped cells, an N-type dopant is deeply implanted into the surface of the semiconductor substrate 315 and the bottom surfaces of the trenches so that the high-concentration diffusion areas 346 and 347 are formed. As well-known, in the method for forming single crystalline silicon, an amorphous silicon or polycrystalline silicon layer is formed at the locations where the diffusion regions 317 of the second stepped cells will be formed, i.e., the bottom surfaces of the trenches. Then, the amorphous silicon or polycrystalline silicon layer is changed into a single crystalline silicon layer by using a solid phase epitaxial growth method, thereby forming the single crystalline silicon. The change into the single crystalline silicon layer can be made by irradiating laser light instead of the solid phase epitaxial growth method.

Since the high-concentration diffusion areas 346 and 347 are formed in a self-alignment manner, the high-concentration diffusion areas 346 and 347 are formed by implanting ions in an arrow direction with respect to all of the first step height cells 386 and the second step height cells 387 on the memory array. The high-concentration diffusion areas 346 and 347 will form a double-layer laminate structure with low-concentration diffusion areas which will be described later.

Next, as shown in FIG. 19B, an N-type dopant is shallowly implanted into the surface of the semiconductor substrate 315 and the bottom surfaces of the trenches, so that the low-concentration diffusion areas 316 and 317 are formed. The low-concentration diffusion areas configure Schottky diode structures together with second electrodes which will be described later. Also, as shown in FIG. 19B, the low-concentration diffusion areas 316 and 317 form a double-layer laminate structure with the high-concentration diffusion areas 346 and 347.

Likewise, since the low-concentration diffusion areas 316 and 317 are formed in a self-alignment manner, the low-concentration diffusion areas 316 and 317 are formed by implanting ions in an arrow direction with respect to all of the first step height cells 386 and the second step height cells 387 on the memory array. The reason why the low-concentration diffusion areas 316 and 317 can be formed in a self-alignment manner is because the trench structures and the sidewall spacers 325 act as a mask.

As shown in FIG. 19B, the low-concentration diffusion areas 316 formed in the surface of the semiconductor substrate 315 become semiconductor layers that form the first step height cells 386 as shown in FIGS. 6 and 7.

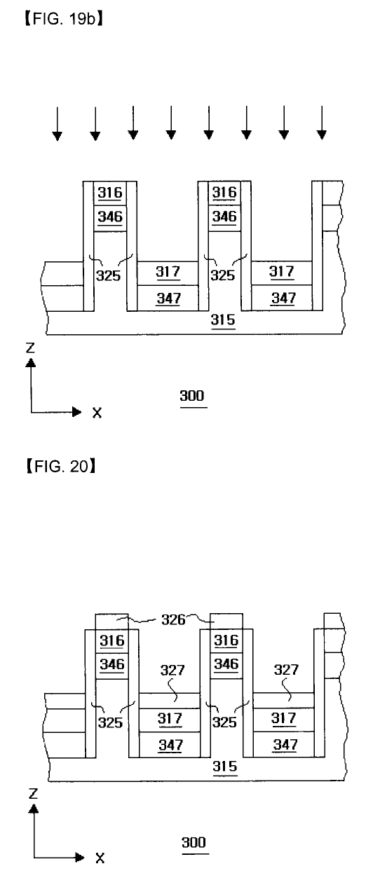

Next, as shown in FIG. 20, silicide or a metal is applied as second electrodes 326 and 327 of a thin oxide layer 335 on the diffusion areas 316 and 317.

The second electrodes 326 and 327 are formed by patterning using photolithography and etching after applying the silicide or metal on the diffusion areas 316 and 317. Then, an insulating layer (not shown) is deposited to fill space between the patterned second electrodes 326 and 327, and planarization is performed.

The second electrodes 326 and 327 form Schottky diodes, as shown in FIG. 1, together with the diffusion areas 316 and 317. In order to form Schottky diodes as shown in FIG. 3, the diffusion areas 316 and 317 are used as second electrodes of the oxide layer 335 without forming silicide or a metal.

Next, as shown in FIG. 21, the thin oxide layer 335 is deposited or thermally grown. The oxide layer 335 is formed with a thin thickness in order to lower a VPP voltage for programming. In order to simplify the fabricating process, the thickness of the oxide layer 335 is preferably similar to that of the gate oxide layers of thin oxide film transistors.

When the thin oxide layer 335 is thermally grown on the second electrodes 326 and 327 formed of silicide or metal, the thickness or properties of the grown oxide layer 335 may change from those of an oxide layer grown on a semiconductor surface. Accordingly, a polycrystalline silicon layer (not shown) is deposited and patterned, and then the oxide layer 335 may be thermally grown.

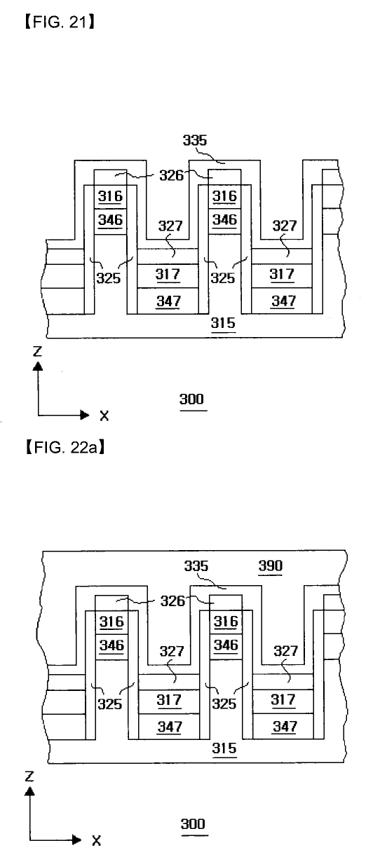

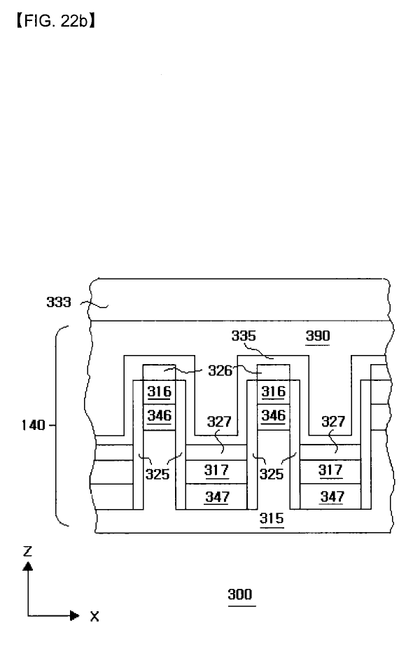

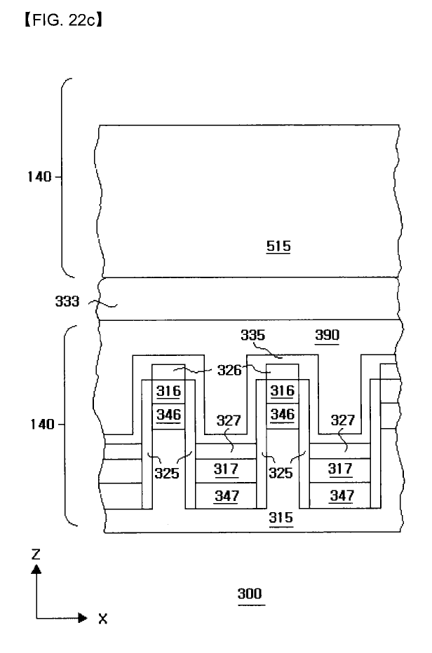

Next, as shown in FIG. 22A, a silicide layer, a metal layer, or a polycrystalline silicon layer is formed as a first electrode 390 of the thin oxide layer 335 on the thin oxide layer 335. The silicide layer, the metal layer, or the polycrystalline silicon layer is formed by depositing silicide, a metal, or polycrystalline silicon on the thin oxide layer 335 and patterning using photolithography and etching.

The first electrode 390 becomes a conductor connected to word lines or bit lines according to a connection method.

Next, as shown in FIG. 22B, an interlayer insulating layer 333 is deposited and formed. The reason is because memory arrays in a multilayer memory array have to be electrically isolated from each other. FIG. 22B shows the interlayer insulating layer 333 for fabricating a multilayer memory array.

FIG. 22C shows a cross-sectional view after a semiconductor layer 515 is grown and formed on the interlayer insulating layer in order to fabricate the multilayer memory array.

As is well-known in the art, the semiconductor layer 515 may be formed by forming an amorphous silicon layer or a polycrystalline silicon layer on the interlayer insulating layer 333 and performing a solid-phase epitaxy growth method to change the amorphous silicon layer or the polycrystalline silicon layer to a monocrystalline silicon layer. Or the semiconductor layer 515 may be formed by changing the amorphous silicon layer or the polycrystalline silicon layer to a moncrystalline silicon layer through laser irradiation instead of the solid-state epitaxy growth method based on heat treatment.

Since the monocrystalline silicon semiconductor layer is formed of the same monocrystalline silicon as the semiconductor substrate described above, and performs the same function as the semiconductor substrate, the semiconductor layer can be substituted for the semiconductor substrate. Accordingly, by repeating operations described above with reference to FIGS. 16 through 22B, another single-layer memory array may be stacked. Accordingly, repeated descriptions of the same operations will be omitted.

In this way, a multilayer memory array is fabricated, and word lines, bit lines, and body electrodes connected to the respective memory arrays are formed to be connected into circuits through a well-known metal wiring process.

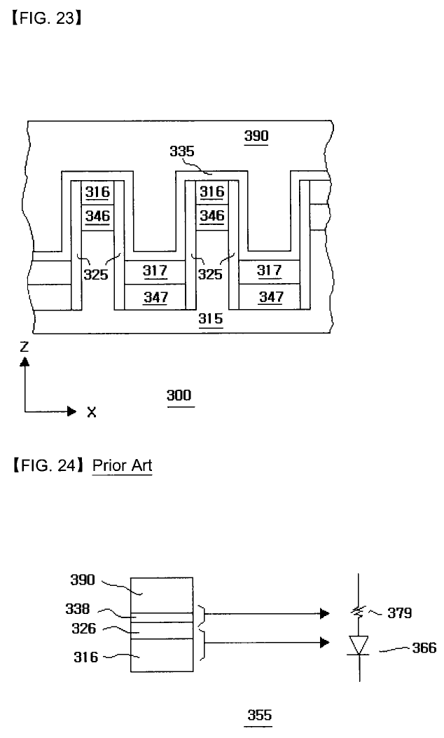

FIG. 23 shows the case where operation of forming silicide layers or metal layers as the second electrodes 326 is omitted in the structure shown in FIG. 20. Accordingly, in the structure shown in FIG. 23, the diffusion areas 316 and 317 are used as second electrodes.

Referring to FIG. 23, when the thin oxide layer 335 is in a conductive state, the first electrode 390 has to be formed of silicide or a metal, not polycrystalline silicon, in order to form Schottky diodes with the second electrodes 326 and 327.

A conventional memory cell is shown in FIG. 24. The memory cell has a structure of conductive layer (390, a first electrode)-variable resistor (338, an intermediate layer)-conductive layer (326, a second electrode)-semiconductor layer (316). FIG. 24 shows a cross-sectional view of a B-type memory cell in which the intermediate layer between the first electrode 390 and the second electrode 326 is a variable resistor 338, and shows an equivalent circuit of the B-type memory cell.

As shown in FIG. 24, the variable resistor 338 is interposed between the first electrode 390 that is a conductive layer and the second electrode 326 that is formed of a metal, thereby forming a variable resistive device 379.

Also, as shown in FIG. 24, due to the contact of the second electrode 326 with a diffusion area 316 doped with a low concentration of P-type or N-type dopant, a Schottky diode 366 is formed.

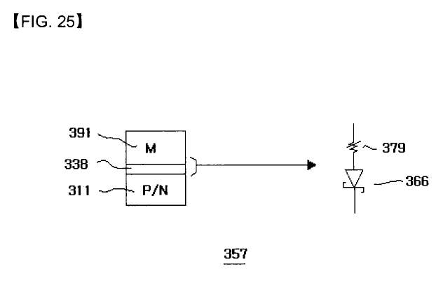

A memory cell according to an embodiment of the inventive concept is shown in FIG. 25. The memory cell has a structure of conductive layer (391, a first electrode)-variable resistor (338, an intermediate layer)-semiconductor layer (311, a second electrode). FIG. 25 shows a cross-sectional view of a B-type memory cell in which an intermediate data between the first electrode 391 and the second electrode 311 is a variable resistor 338, and shows an equivalent circuit of the B-type memory cell.

As shown in FIG. 25, the variable resistor 338 is interposed between the first electrode 391 formed of a metal and the second electrode 311 doped with a low concentration of dopant.

That is, the memory cell configures a Schottky diode including a variable-resistance device. In FIG. 25, the memory cell is shown as an equivalent circuit in which a variable-resistance device is connected in series to a Schottky diode 366.

The memory array including the B-type memory cell is similar to a memory array including an A-type memory cell. Therefore, a method of fabricating a B-type memory array is also similar to a method of fabricating an A-type memory array. That is, the B-type memory array may be formed by applying a variable resistor, instead of an insulating layer, as an intermediate layer with a predetermined thickness to form first and second step height cells in the memory array fabrication method as described above.

Since the remaining processes are the same as those of the above-described memory array fabrication method, detailed descriptions thereof will be omitted.

The operation method of a non-volatile memory (hereinafter, referred to as an A-type non-volatile memory) including the A-type memory cell is also similar to the operation method of a non-volatile memory (hereinafter, referred to as a B-type non-volatile memory) including the B-type memory cell, except that the intermediate layer (that is, the insulating layer) that is a storage area of the A-type non-volatile memory cannot change from a low resistance state to a high resistance state, unlike the variable resistor of the B-type non-volatile memory. Accordingly, the embodiments related to the circuit and operation of the A-type memory device, as described above, can be applied to a B-type memory device. Repeated descriptions thereof will be omitted. For example, the VPP voltage which is a program voltage as described above is a voltage at which a resistive path is made in an insulating layer, and if the VPP voltage is applied to the insulating layer, the insulating layer changes to a low resistance state from a high resistance state.

Likewise, in the case of the variable resistor, when a set voltage is applied to the variable resistor, the variable resistor changes to a low resistance state from a high resistance state.

Accordingly, the VPP voltage which is the program voltage may be adjusted to the set voltage for the variable resistor, and may be programmed by a program method similar to that applied to the A-type memory device.

Also, the VPP voltage which is the program voltage may be adjusted to a reset voltage for the variable resistor, and when the reset voltage is applied to the variable resistor, the variable resistor may change from a low resistance state to a high resistance state, that is, to an unprogrammed state.

Also, since the B-type memory device reads stored data by determining whether the resistance of the insulating layer or the variable resistor is high or low, like the A-type memory device, the read operation or circuit of the B-type memory device is similar to that of the A-type memory device.

The variable resistor is made of a variable-resistance material, a phase change material, or a material capable of implementing two stable resistance states to obtain memory properties.

The variable-resistance material may be perovskite, a transition metal oxide, chalcogenide, etc. The variable-resistance material is a material whose electrical resistance changes to a low resistance state or a high resistance state in response to a specific voltage. For example, the variable-resistance material may be a two component system transition metal oxide, such as TiO₂, NiO, HfO₂, Al₂O₃, ZrO₂, ZnO, Ta₂O₅, and Nb₂O₅, a three component system transition metal oxide, such as SrTiO₃, HfAlO, HfSiO, and HfTiO, or their combination. Also, the variable-resistance material is SiO₂ doped with Cu, SiO₂ doped with Ag, a Ge—Se—Te compound doped with Cu, a Ge—Se—Te compound doped with Ag, a CuOₓ-based variable-resistance material, or their combination.

The phase change material is a material that phase-transitions to a crystalline state or an amorphous state in response to application of a specific current. The phase change material may be a chalcogenide compound. The chalcogenide compound may be a two component system compound, a three component system compound, or a four component system compound, made by a combination of Ge, Te, Sb, In, Se, and Sn. Also, the chalcogenide compound may be made by adding Bi to the two, three, or four component system compound. Preferably, the phase change material is Ge₂Sb₂Te₅, Ge₂Sb₂Te₅ doped with N₂, O₂, SiO₂, or Bi₂O₃, or their combination.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

1. A non-volatile memory, wherein
a plurality of semiconductor layers are stacked on a semiconductor substrate to form a multilayered semiconductor layer, a plurality of interlayer insulating layers are respectively formed between the semiconductor substrate and the lowest one of the semiconductor layers and between the semiconductor layers,
a plurality of first step height cells and a plurality of second step height cells having a different step height than the first step height cells are formed on the semiconductor substrate or on each semiconductor layer of the multilayered semiconductor layer, each of the first step height cells and the second step height cells is configured to have one of a first multilayer laminate structure including a conductive layer (a first electrode)—a variable resistor (an intermediate layer)—a conductive layer (a second electrode)—a semiconductor layer, a second multilayer laminate structure including the conductive layer (the first electrode)—the variable resistor (the intermediate layer)—the semiconductor layer (the second electrode), and a third multilayer laminate structure including the conductive layer (the first electrode)-an insulating layer (the intermediate layer)—the conductive layer (the second electrode)—the semiconductor layer, and a fourth multilayer laminate structure including the conductive layer (the first electrode)—the insulating layer (the intermediate layer)—the semiconductor layer (the second electrode), the first step height cells are formed with respect to a horizontal surface and have a greater step height than the second step height cells, and the second step height cells are formed with respect to a horizontal surface and have a lesser step height than the first step height cells.

2. The non-volatile memory according to claim 1, wherein each of the semiconductor layers configuring the first step height cells and the second step height cells includes a low-concentration diffusion area and a high-concentration diffusion area, and the low-concentration diffusion area and the high-concentration diffusion area are configured in a double-layer laminate structure.

3. The non-volatile memory according to claim 2, wherein the high-concentration diffusion area is formed below the low-concentration diffusion area in a double-layer laminate structure, and specific resistance of the high-concentration diffusion area is lower than specific resistance of the low-concentration diffusion area, so that the high-concentration diffusion area is used as a word line or a bit line.

4. The non-volatile memory according to claim 1, wherein the first step height cells are formed with respect to the surface of the semiconductor substrate or the surface of the semiconductor layer, and the second step height cells are formed with respect to the bottom surfaces of trenches.

5. The non-volatile memory according to claim 1, wherein a plurality of sidewall spacers are formed on sidewalls between the first step height cells and the second step height cells.

6. The non-volatile memory according to claim 2, wherein the first electrode is connected to the word line and the low-concentration diffusion area or the high-concentration diffusion area of each semiconductor layer is connected to the bit line, or the first electrode is connected to the bit line and the low-concentration diffusion area or the high-concentration diffusion area of the semiconductor layer is connected to the word line, and the first step height cells or the second step height cells are formed at intersections of word lines and bit lines as seen from the top.

7. A method of fabricating a non-volatile memory, comprising:
forming a plurality of first step height cells and a plurality of second step height cells on a semiconductor substrate by forming a plurality of trenches in the semiconductor substrate in a direction corresponding to areas in which the second step height cells are to be formed, forming a plurality of sidewall spacers on the sidewalls of the trenches, forming a plurality of diffusion areas in a self-alignment manner, forming the first step height cells on the surface of the semiconductor substrate, forming the second step height cells on bottom surfaces of the trenches, and forming a plurality of first electrodes of the first step height cells and the second step height cells;
forming an interlayer insulating layer on the semiconductor substrate on which the first step height cells and the second step height cells are formed;
applying a semiconductor layer on the interlayer insulating layer; and
forming a plurality of first step height cells and a plurality of second step height cells on the semiconductor layer by forming a plurality of trenches in the semiconductor substrate in a direction corresponding to areas in which the second step height cells are to be formed, forming a plurality of sidewall spacers on the sidewalls of the trenches, forming a plurality of diffusion areas in a self-alignment manner, forming the first step height cells on the surface of the semiconductor substrate, forming the second step height cells on bottom surfaces of the trenches, and forming a plurality of first electrodes of the first step height cells and the second step height cells,
wherein each of the first step height cells and the second step height cells has one of a first multilayer laminate structure including a conductive layer (a first electrode)—a variable resistor (an intermediate layer)—a conductive layer (a second electrode)—a semiconductor layer, a second multilayer laminate structure including the conductive layer (the first electrode)—the variable resistor (the intermediate layer)—the semiconductor layer (the second electrode), and a third multilayer laminate structure including the conductive layer (the first electrode)—an insulating layer (the intermediate layer)—the conductive layer (the second electrode)—the semiconductor layer, and a fourth multilayer laminate structure including the conductive layer (the first electrode)—the insulating layer (the intermediate layer)—the semiconductor layer (the second electrode).

8. The method according to claim 7, wherein each of the semiconductor layers configuring the first step height cells and the second step height cells includes a low-concentration diffusion area and a high-concentration diffusion area, and the low-concentration diffusion area and the high-concentration diffusion area are configured in a double-layer laminate structure.

9. The method according to claim 7, wherein each high-concentration diffusion area is formed by doping to a high concentration with a dopant that is complementary to the semiconductor substrate or the semiconductor layer, and each low-concentration diffusion area is formed by doping to a low concentration with the dopant, so that the high-concentration diffusion area is formed below the low-concentration diffusion area in a double-layer laminate structure.

10. The method according to claim 7, wherein in the case where the insulating layer (the intermediate layer) configuring the first step height cells and the second step height cells is thermally grown on the conductive layer (the second electrode), a polycrystalline silicon layer is deposited and patterned on the conductive layer (the second electrode) before the insulating layer (the intermediate layer) is thermally grown.

11. The non-volatile memory according to claim 1, wherein each of the semiconductor layers configuring the first step height cells and the second step height cells may include a P-N junction diode structure.

12. The non-volatile memory according to claim 1, wherein each of the semiconductor layers configuring the first step height cells and the second step height cells, if the variable resistor or insulating layer is in a conducting state, the conductive layer and the semiconductor layer may become a Schottky diode structure.

13. The non-volatile memory according to claim 3, wherein the first electrode is connected to the word line and the low-concentration diffusion area or the high-concentration diffusion area of each semiconductor layer is connected to the bit line, or the first electrode is connected to the bit line and the low-concentration diffusion area or the high-concentration diffusion area of the semiconductor layer is connected to the word line, and the first step height cells or the second step height cells are formed at intersections of word lines and bit lines as seen from the top.

14. The method according to claim 8, wherein each high-concentration diffusion area is formed by doping to a high concentration with a dopant that is complementary to the semiconductor substrate or the semiconductor layer, and each low-concentration diffusion area is formed by doping to a low concentration with the dopant, so that the high-concentration diffusion area is formed below the low-concentration diffusion area in a double-layer laminate structure.
